(19) United States
(12) Patent Application Publication
(10) Pub. No.: US 2007/0211523 A1
(43) Pub. Date: Sep. 13, 2007

(54) Magnetic random access memory

(75) Inventor: Juhan Kim, San Jose, CA (US)

Correspondence Address: JUHAN KIM, 5890 W. WALBROOK DR., SAN JOSE, CA, 95129, US

(73) Assignee: Juhan Kim, San Jose, CA (US)

(21) Appl. No.: 11/615,937

(22) Filed: Dec. 23, 2006

Related U.S. Application Data
(63) Continuation of application No. 11/308,097, filed on Mar. 7, 2006.

(51) Int. Cl. G11C 11/00

(52) U.S. Cl. 365/158

(57) ABSTRACT

A magnetic memory includes a diode as an access device instead of MOS transistor and a magnetoresistive storage serves as a storage element, wherein the diode has four terminals, the first terminal is connected to a read word line, the second terminal serves as a storage node, the third terminal is floating, the fourth terminal is connected to a bit line, and wherein the magnetoresistive storage includes MTJ (magnetic tunnel junction) stack, the first electrode of the stack is connected to the storage node, the second electrode of the stack is connected to a free magnetic layer which serves as a resistor line, those electrodes are isolated by insulation layer, and the stack is coupled to a pinned magnetic layer which serves as a write word line. The diode also serves as a current amplifier with controlling the storage node through the storage element when the resistor line is asserted to measure the resistance of the storage element during read. And current-to-voltage converter receives the current output of the current amplifier, and transfers voltage output to the sense amp which amplifies the received voltage from the (main) memory cell and the reference voltage from the dummy memory cell(s). After latching data, the sense amp output cuts off the current path of the bit line. In the present invention, the memory cells are formed in between the routing layers. Hence the memory cells can be stacked over the peripheral circuits and alternatively multiple cells can be stacked.

### FIELD OF THE INVENTION

The present invention relates generally to integrated circuits, in particular to the MRAM (Magnetic Random Access Memory).

### BACKGROUND OF THE INVENTION

With conventional MOS (Metal-Oxide Semiconductor) access transistor approaching their speed and scaling limits, four-terminal the diode can replace MOS transistor as an access device for the next-generation memories. In the present invention, the diode serves as an access device for MRAM (Magnetic Random Access Memory or Magnetoresistive Random Access memory). Four-terminal the diode is more flexible than two-terminal the diode, three-terminal bipolar transistor or three-terminal MOS transistor (body is biased to the constant voltage), in order to control the magnetic memory such that the four-terminal the diode is used for read operation, and three-terminal bipolar transistor is used for write operation respectively. Furthermore, the diode serves as a sense amplifier when read. In addition, the bipolar devices can flow sufficient current to read through the whole junction, thus the access time can be reduced. In contrast, MOS transistor can flow only weak current through the shallow inversion layer. Hence the access time is limited by the MOS transistor.

In FIGS. 1A and 1B, a prior art of magnetic memory including MOS access transistor and sense amplifier is illustrated. Magnetic memory cell 100 includes a magnetoresistive storage element 107, wherein one side of the magnetoresistive storage element is connected to the bit line 106, and the other side of the storage element is connected to the drain 112 of MOS transistor 111. The read word line 101 is connected to the gate of MOS transistor, and the source 113 and the body 115 are connected to ground. The write word line 108 couples to the storage element 107. In order to access magnetoresistive storage element, MOS transistor 111 should be turned on by the read word line 101. However, the turn-on resistance of the MOS transistor is relatively high. The read path of the memory cell includes a high turn-on resistance of the MOS transistor and resistive storage element. This is one of the limitations of the MOS transistor as an access device for magnetic memory. The high resistive MOS transistor and another high resistive storage element are not a good combination to read data, as reported, “A High-Speed 128-kb MRAM Core for Future Universal Memory Applications”, IEEE Journal of Solid-State Circuits, Vol., 39, No. 4 April 2004. And “A 4-Mb 0.18-um 1T1MTJ Toggle MRAM With Balanced Three Input Sensing Scheme and Locally Mirrored Unidirectional Write Drivers”, IEEE Journal of Solid-State Circuits, Vol. 40, No. 1, January 2005.

The capacitance of the bit line would be big because the MOS access device can not isolate the capacitance of the magnetoresistive storage element from the bit line. And the junction capacitance of the MOS access transistor adds more capacitance to the bit line. When read, the MOS access transistor discharges the bit line, and the sense amplifier 110 compares the discharged voltage of the bit line 106 with reference voltage VREF. The discharging time of the bit line is relative longer with heavy capacitive load. Generally, the sense amplifier 110 needs the waiting time to start sensing the bit line, which time is the discharging time of the bit line. As shown in FIG. 1A, the discharging path of the bit line has a magnetoresistive storage 107 and a MOS transistor 111. The magnetoresistive storage has cell-to-cell, wafer-to-wafer variations, and MOS transistors vary as well. In this respect, there are so much variations in the input of the sense amplifier, which is an issue of the prior art of the memory cell and sense amplifier. Moreover, the access time is still slow with long discharging time, around 5 ns. Additionally, sensing margin may not enough because magnetoresistance ratio (MR) is 20-35%, in most of the magnetoresistance material, as published.

In FIG. 1B, the cross sectional view of the magnetoresistive storage element 127 is illustrated, as the prior art, wherein the magnetoresistive storage element 127 is connected to the bit line 126, the write word line 128 couples to the storage element 127, and the storage element 127 is connected to the drain 122 of the MOS access device (111 in FIG. 1A). In order to write, the write word line 128 serves as a pinned magnetic layer, and flows current to a fixed orientation. In contrast, the bit line 126 serves as a free magnetic layer. The magnetic orientation of the free magnetic layer can be switched between two stable states when sufficient magnetic field is applied. Conductors above and below the magnetoresistive storage element 127 known as the magnetic tunnel junction (MTJ), generate the fields necessary to switch the state of the free magnetic layer, where write pulse is around 1.5 ns, as reported. One more limitation in the prior art for write operation, the write driver circuit (not shown) uses MOS transistor-based current source, in order to control the amount of the current flow with the current source (current limiter). The write driver circuit is relatively big because the write current is very high, about 5 mA. Generally, driver circuit including MOS transistor uses multiple parallel devices and occupies wider space than any other control circuits. Thus, write drive circuit should be improved more efficiently.

In these respects, there are needs to replace MOS transistor in the magnetic memory with a more efficient switching device. In order to replace MOS transistor, more sophisticated circuit techniques are required. In the present invention, four-terminal diode serves as a read access device and bipolar current mirror serves as a write driver for magnetic memory. Bipolar current mirror is similar to the MOS current mirror in operation. However, four-terminal diode is quite different from the conventional MOS transistor in order to apply to the magnetic memory, wherein four-terminal diode is known as Shockley diode or thyristor, is a solid-state semiconductor device similar to two-terminal p-n diode, with an extra terminal which is used to turn it on. Once turned on, the diode (p-n-p-n diode or n-p-n-p diode) will remain on conducting state as long as there is a significant current flowing through it. If the current falls to zero, the device switches off. The diode has four layers, with each layer consisting of an alternately p-type or n-type material, for example p-n-p-n and n-p-n-p. The main terminals, labeled anode and cathode, are across the full four layers, and the control terminal, called the gate, is attached to one of the middle layers. The operation of the diode can be understood in terms of a pair of tightly coupled transistors, arranged to cause the self-latching action.

The diodes are mainly used where high currents and voltages are involved, and are often used to control alternating currents, where the change of polarity of the current causes the device to automatically switch off; referred to as ‘zero cross operation’. The device can also be said to be in synchronous operation as, once the device is open, it conducts in phase with the voltage applied over its anode to cathode junction. This is not to be confused with symmetrical operation, as the output is unidirectional, flowing only from anode to cathode, and so is asymmetrical in nature. These properties are used control the desired load regulation by adjusting the frequency of the trigger signal at the gate. The load regulation possible is broad as semiconductor based devices are capable of switching at extremely high speeds over extremely large numbers of switching cycles.

In FIG. 1C, the schematic of p-n-p-n diode 130 is illustrated. It consists of four terminals, such that the anode 131 is connected to power supply or regulating node, the base 132 of p-n-p transistor 135 serves as the collector 132 of n-p-n transistor 134, the collector 133 of p-n-p transistor 135 serves as the base of n-p-n transistor 134 which is controlled by the voltage controller 136. In order to turn on the diode and hold the state of turn-on, the voltage controller should raise the voltage from ground level to VF (forward bias, 0.6 v˜0.8 v for silicon). And the voltage controller 136 should supply the current 137, referred as the base current, which current depends on the characteristic of transistor 134 and 135. Once the base current 137 establishes the forward bias (VF), the collector 132 of n-p-n transistor 134 holds the current path 139 from the base of p-n-p transistor 135. After then, p-n-p transistor 135 is turned on because the base 132 has forward bias from the emitter 131. This sets up the current path 138 which can keep the turn-on state. This is the holding state as long as the base has not so much leakage to drive the base voltage under forward bias (VF) even though the voltage controller 136 is open. To turn off the diode, the voltage controller 136 should lower the voltage of the base of n-p-n transistor 134 under forward bias. To do so, the voltage controller 136 should (negatively) flow more current than the current path 138.

The diode can hold the states of turn-on or turn-off. There are prior arts to use the diode itself as a memory device, such as, “High density planar SRAM cell using bipolar latch-up and gated the diode breakdown”, U.S. Pat. No. 6,104,045, and “Thyristor-type memory device” U.S. Pat. No. 6,967,358, and “Semiconductor capacitively-coupled negative differential resistance device and its applications in high-density high-speed memories and in power switches”, U.S. Pat. No. 6,229,161, and “A novel capacitor-less DRAM cell Thin Capacitively-Coupled Thyristor (TCCT)”, IEDM 2005. These types of memories are volatile memory because the data is stored in the capacitor of the control gate. The data stored in the capacitor can be lost quickly by those leakages when silicon oxide (SiO₂) capacitor stores data, and hence refresh operations are required to sustain data for long time.

In the present invention, magnetoresistive storage element is used as a storage element, and four-terminal the diode replaces the MOS access device as a switching element, not holding device. However four-terminal the diode can not easily replace the MOS transistor as an access device because it has unidirectional current control characteristic and internal feedback loop. Now the present invention devotes to replace MOS transistor with the diode as an access device and sophisticated circuit techniques are introduced to control the diode for the magnetoresistive storage element. The diode can work for the memory devices as a switching element, not a storage element. Furthermore, the diode serves as an amplifier in order to enhance the amplification factor when read. It gives as many as advantages to design and fabricate it on the wafer.

The conventional MOS access transistor has a parasitic bipolar transistor 115, as shown in FIG. 1A, wherein the base 114 controls the emitter/collector 112 and 113, and the base 114 serves as the body of the MOS transistor 111. During read and write, the base (body) 114 is at ground (or negative) to prevent bipolar effect. The parasitic bipolar transistor is not wanted device in the conventional memories which is usually turned off by applying ground or reverse voltage, but now adding one more terminal to the parasitic bipolar transistor in the conventional memory, a p-n-p-n diode (or n-p-n-p) can serve as an access device for the next generation memory devices with good performance and simple structure.

Furthermore, in the present invention, the write driver circuit can be improved by using bipolar current mirror, which can flow more current, and occupy small area, compared to the MOS transistor driver circuit.

### SUMMARY OF THE INVENTION

In the present invention, magnetic random access memory including four-terminal the diode access device is realized. The memory cell includes magnetoresistive storage element and four-terminal the diode access device, which combination is less complicated to fabricate, compared to combining complex MOS device. Replacing MOS access transistor with a diode as a switching device in the memory cell, there are as many as advantages to configure memory arrays. And the diode need not be a high performance device nor have a high current gain, and also serves as a sense amplifier when read. However the operation of the diode is not as simple as that of MOS transistor because it has internal feedback loop and unidirectional current control in nature even though it has almost no parasitic effects, as long as punch-through is simply avoided in the base region with optimal length. In the present invention, the sophisticated circuit techniques are introduced to use the diode as an access device for the magnetoresistive storage element. In addition, the cell structures are illustrated, which are practical and mass producible with the current CMOS process environment.

Removing MOS device from the memory cell, the cell structure is simplified, which enables to form the memory cell in between the routing metal layers, which can reduce cell area dramatically with no performance degradation. And the present invention can be implemented on the bulk and SOI wafer, which makes to integrate high density memory and control circuit on a chip, regardless of the process and fabrication facility. In doing so, it is more flexible to fabricate the memory chip, such that the process of the memory cell is independent of the MOS process. Hence, topping the memory cell is another fabrication facility which has prepared to deposit the dedicated material, after fabricating the base layers including the MOS transistors in a fabrication facility, because most of fabrication facilities provide the standard MOS transistor.

Various types of the diode can be applied to form the diode access device, such as silicon including solid-state, amorphous and stretchable silicon, germanium, GaAs, SiGe, metal-semiconductor the diode (Schottky diode) and so on.

Low power consumption is realized, because the word line cuts off the holding current during standby. Thus there is no standby current in the memory cell. Active power is also reduced with self-closing data latch, wherein the latch output cuts off the bit line current after latching the stored data. Thus, low power consumption suppresses ‘Joule heating’, which may reduce gate delay and achieve high yield.

The memory operation is fast and stable. The diode output can be transferred to the bit line quickly, because the diode current is generally much higher than that of MOS transistor. The diode generates more current with its whole junction area while MOS transistor generates current with inversion layer on the surface. The four-terminal diode amplifies the read current from the word line to the bit line, wherein the storage element controls the base current when read. Thus the diode serves as a sense amplifier, which realizes more accurate sensing and also achieves fast access time. In the present invention, more flexible array architectures are introduced as well, in order to apply the magnetic memory array for the proper system applications. For the high density system, single memory cell stores a datum and two dummy cells generate reference voltage for sensing with slow access time. And for the low density and high speed system, dual memory cells store a datum, wherein one memory cell stores non-inverting data and another memory cell stores inverting data. Thus inverting data generates a reference voltage with no dummy cells and reduces access time with self-generating reference voltage. Hence, more accurate sensing is achieved because the magnetoresistive storage element has low magnetoresistance ratio (MR) ratio 20˜35% (0.2˜0.35 times) which is lower than that of other resistance storage element, such that phase change memory has around 100 times of the resistance difference between high data and low data.

The write driver circuit can be improved by using bipolar current mirror, which can flow more current, and occupy small area, compared to the MOS transistor driver circuit.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings which are incorporated in and form a part of this specification, illustrate embodiments of the invention and together with the description, serve to explain the principles of the invention.

FIG. 1A illustrates the prior art of the magnetic memory including the MOS access transistor. FIG. 1B illustrates the prior art of the magnetoresistive storage element. FIG. 1C illustrates the p-n-p-n diode of the prior art.

FIG. 2A illustrates the magnetic memory cell, according to the teachings of the present invention.

FIG. 3 illustrates the memory array in order to explain how to select a cell from the matrix, according to the teachings of the present invention.

FIG. 4 illustrates array architecture wherein single cell stores a datum, according to the teachings of the present invention.

FIG. 5A illustrates the array architecture including dummy row, according to the teachings of the present invention. FIG. 5B illustrates voltage reference circuit including dummy cells, according to the teachings of the present invention.

FIG. 6A illustrates read timing, according to the teachings of the present invention. FIG. 6B illustrates I-V curve of the memory, according to the teachings of the present invention.

FIG. 7 illustrates array architecture wherein dual cells store a datum, according to the teachings of the present invention.

FIG. 8A illustrates the write operation, according to the teachings of the present invention. FIG. 8B illustrates the timing diagram for the write data “1”, according to the teachings of the present invention. FIG. 8C illustrates the timing diagram for the write data “0”, according to the teachings of the present invention.

FIG. 9A illustrates the cross sectional view of the magnetic memory cell on the wafer, as the present invention. FIG. 9B illustrates top view of the magnetic memory cell, as the present invention.

FIG. 10 illustrates the cross sectional view of the magnetic memory cell on the MOS transistor, as the present invention.

FIG. 11A to 11G illustrate the brief process steps for fabricating the magnetic memory cell, according to the teachings of the present invention.

FIG. 12A illustrates the cross sectional view of the magnetic memory cell on the MOS transistor, and, FIG. 12B illustrates the cross sectional view of the stacked magnetic memory cell as the present invention.

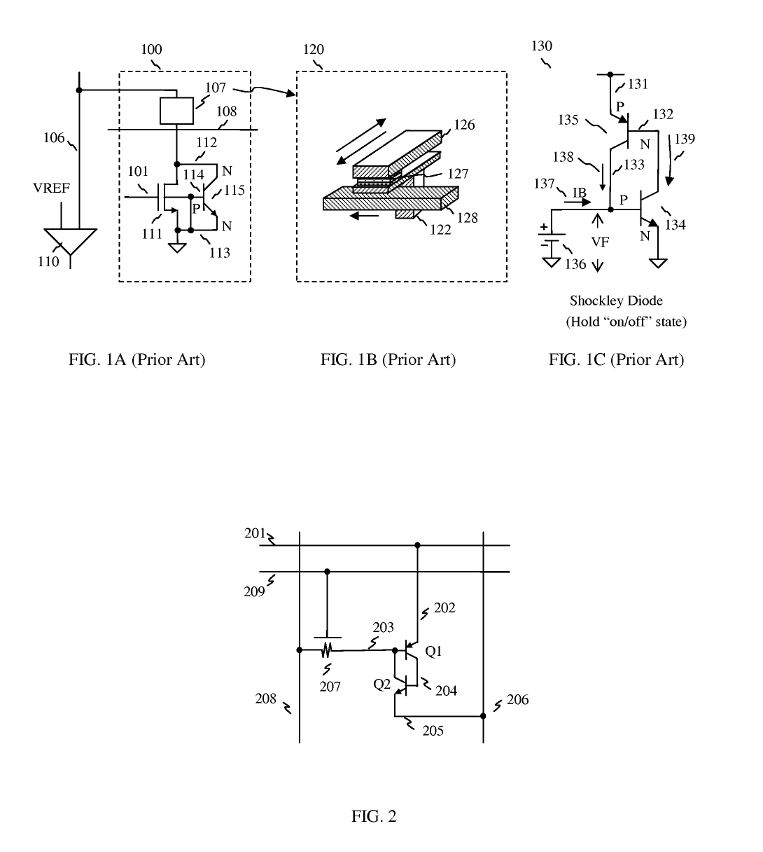

### DETAILED DESCRIPTION OF PREFERRED EMBODIMENT(S)

Reference is made in detail to the preferred embodiments of the invention. While the invention is described in conjunction with the preferred embodiments, the invention is not intended to be limited by these preferred embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

Detailed descriptions for the present invention are described as follows, which include the schematics, the timings and cross sectional views.

In FIG. 2A, a magnetic memory cell including a four-terminal diode as an access device and a magnetoresistive storage element is illustrated as the present invention. Generally, four-terminal diode (p-n-p-n diode, known as Shockley diode) is described as a p-n-p transistor Q1 and an n-p-n transistor Q2 which form a feedback loop. Once turned on, p-n-p-n diode will remain on conducting state with the feedback loop, as long as there is a significant current flowing through it. The diode includes four terminals, wherein the first terminal 202 is p-type and connected to a read word line (WL) 201 to activate the memory cell, the second terminal 203 is n-type and connected to one side of the storage element 207, the third terminal 204 is p-type and floating, the fourth terminal 205 is n-type and connected to a bit line (BL) 206 to write or read data. The other side of the storage element 207 is connected to a resistor line (RL) 208 which sets up the current path of the diode when write or read. And the storage element 207 includes magnetic tunnel junction (MTJ) stack as a magnetoresistive storage element, wherein one node of the storage element is connected to the second terminal of the diode which serves as a storage node 203, another node of the storage element is connected to the resistor line 208 which serves as a free magnetic layer, and one more layer is isolated from the magnetic tunnel junction stack, which layer serves as a pinned magnetic layer and is connected to a write word line 209 in perpendicular direction to the free magnetic layer.

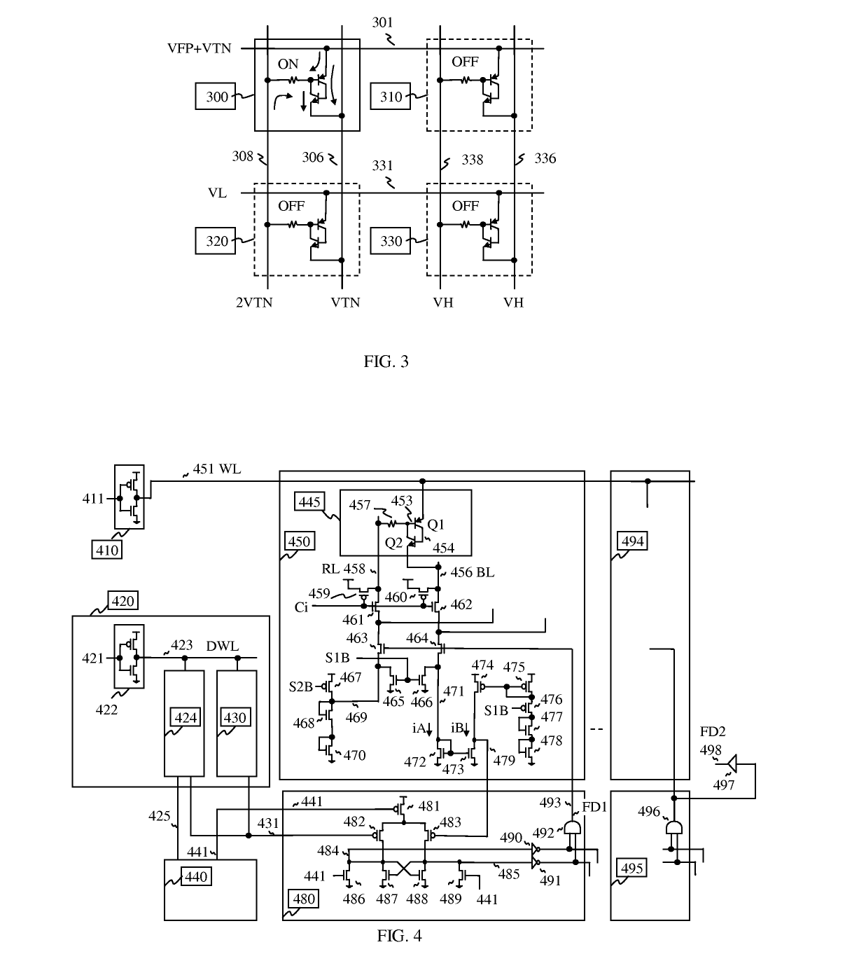

In FIG. 3, the decoding scheme of the memory array is illustrated in order to explain how to select a cell from the matrix during read operation, as the present invention, wherein the selected cell 300 is turned on after the forward bias is established from the word line to the bit line, and the resistor line 308 is higher than the bit line to measure the storage element. More accurately, the word line voltage is near the sum of VFP (built-in voltage of diode) and VTN (threshold voltage of the MOS transistor, 472 in FIG. 4), and the resistor line voltage is near 2VTN when read, where the collector-emitter voltage of the bipolar transistors are negligibly low when the bipolar transistors are fully turned on with very low turn-on resistance (lower than 0.1V). More detailed memory operation will be explained as below (in FIG. 4). In contrast, the unselected cell 310 is turned off because the bit line 336 and the resistor line 338 keep VH level (high voltage of the memory array), thus reverse bias is established, where the word line voltage is lower than the bit line and the resistor line. And the unselected memory cell 320 and 330 are turned off as well, because the word line 331 is at VL level (ground level of the memory array), thus reverse bias is set up from the word line to the resistor line and the bit line.

In FIG. 4, the read path is illustrated, as the present invention, wherein the memory array includes the word line driver 410, dummy control circuit 420 including dummy column 424 and 430, sense amp enable circuit 440, the selected column 450, sense amp 480, the far end column 494, and the far end sense amp 495. In this configuration, single memory cell 445 stores a datum, but the dummy columns 424 and 430 store complementary data in order to generate the reference voltage 431 to the sense amp 480. The operation of the dummy control circuit 420 and sense amp enable circuit 440 will be explained as below in FIG. 5. Before explaining the dummy cell operation, the operation of the main memory cell 445 is described, such that the column decoder output Ci in the main column 450 is selected to VH level in order to read data, thus the pre-charge device 459 and 460 are turned off, and simultaneously transmission gate 461 and 462 are turned on. By turning on the transmission gate 461 and 462, the resistor line 458 and the bit line 456 are discharged to VL level by the NMOS 465 and 466 through the NMOS 463 and 464 which are turned on by the AND gate 492. After discharged, pull-down devices 465 and 466 are turned off by lowering the control signal S1B, and then the word line 451 is raised by the word line driver 410 when the row decoder output 411 is asserted to VL level. Hence the forward bias is established between the word line 451 and the storage node 453 (at VL level) which serves as the base of the p-n-p Q1 and the collector of n-p-n Q2 as well. After setting up the forward bias, the word line 451 raises the floating node 454 through the p-n-p Q1 which is turned on by the forward bias. The floating node 454 is quickly charged because there is very small parasitic capacitance. After the floating node 454 is reached near the word line voltage, the current path is set up from the word line 451 to the bit line 456.

When the bit line 456 is reached to the threshold voltage of NMOS 472, NMOS 472 is turned on, thus the word line voltage is determined by the sum of the threshold voltage (VTN) of the NMOS 472 and the built-in voltage (VFP) of p-n-p Q1. During the current path is set up, the resistor line 458 is floating. Hence there is no current path and the resistor line voltage is the same as the storage node voltage (near VTN level). After then, in order to measure the resistance value of the storage element 457, the resistor line 458 is raised to 2VTN by turning PMOS 467. When the PMOS 467 is turned on by lowering the control signal S2B, the NMOS 468 and 470 are turned on as well. Thus, the resistor line voltage is limited by the two NMOS 468 and 470 at 2VTN, because the NMOS 468 and 470 have diode-like current curve where gate and drain are connected together, which flows very high current above the threshold voltage. By raising the resistor line 458 to 2VTN level, the storage node 453 is pulled up by the magnetoresistive storage element 457. When the resistance of the storage element 457 is high, the storage node is less pulled up. Hence the current flow through the p-n-p Q1 is slightly reduced. In contrast, when the resistance of the storage element is low, the storage node is pulled up more. Hence, the current flow through the p-n-p Q1 is reduced more. But the current flow through the resistor is increased slightly, which is negligible in this application. In another case, when the resistance of the storage element is very low, the storage node can not sustain the forward bias, thus the p-n-p Q1 is turned off and the current does not flow through the bit line. In this manner, the diode serves as a pre-amp with amplifying the bit line current iA depending on the resistance value of the storage element. Furthermore, when reading the resistance value from the storage element, the threshold voltage of the MOS transistor is sensitive. Thus, low threshold transistor can enhance the sensing speed, which can be used in the current mirror circuit 472 and 473. Also, low threshold transistor can be used in the nodes of 482, 483, 487 and 488 of the sense amp 480, in order to achieve fast access time.

When reading data from the magnetoresistive storage element, the MR ratio is reduced with increasing the measuring voltage depending on the materials. Hence, the measured voltage is determined around the threshold voltage (VTN) of the NMOS in the present invention, which is around 0.3V, in order to obtain enough MR ratio. Generally, the threshold voltage of the MOS transistor is near 0.3V in the resent CMOS technology, as published, “Temperature Dependency 0.1 um Partially Depleted SOI CMOSFET”, IEEE Electron Device Letters, Vol. 22, No. 7. pp. 339, July 2001. In order to measure the resistance value of the storage element within the optimal range, the resistor line voltage is limited by the NMOS 468 and 470 when PMOS is turned on by lowering S2B signal. In this manner, the resistor line 458 can provide a measuring voltage (2VTN) to the resistor when read.

During the bit line current is set up, the current mirror 473 also sets up the current path through the pull-up PMOS 474, where the PMOS 474 is a current mirror of the PMOS 475, the current through PMOS 475 is determined by the total resistance of the pull-down path including NMOS 477 and 478 when the PMOS 476 is turned on by the control signal S1B. When the current mirror 473 set up the current path iB, the output 479 is amplified by the NMOS 473 which configures a conventional amplifier with an active load transistor 474 which has almost constant current. In doing so, the bit line current is converted to voltage output 479 by the amplifier 473 and 474. Now the voltage output 479 is ready for the sensing by the sense amp 480.

During the main column 450 prepares the voltage output 479 from the main memory cell 445, the dummy columns 424 and 430 and sense amp enable circuit 440 prepare the sense amp enable signal 441 and reference bit line voltage 431 (more detailed operation in FIGS. 5A and 5B). When the sense amp enable signal 441 is lowered by the circuit 440, the sense amp 480 is enabled. Before that, the reference voltage 431 is ready. Thus the sense amp starts to amplify, such that the pre-charge device 486 and 489 are turned off, and PMOS 481 is turned on, one of two PMOS 482 and 483 strongly pulls up the latch node 484 or 485. When the magnetoresistive storage element 457 stores high resistance which is data “1”, the bit line current is higher. Hence the inverting amplifier lowers the voltage output 479 with strong pull-down current. The PMOS 483 is stronger than PMOS 482 because the reference voltage 431 is medium level. The latch node 485 is pulled up by the PMOS 483. At the same time, the NMOS 487 pulls down the latch node 484 strongly. In contrast, the NMOS 488 is weaker than the NMOS 487 because the latch node 484 is lower, which is the gate of the NMOS 488. As a result, the latch node 485 is raised near VH level, but the latch node 484 is lowered near VL level. Simultaneously, the output of inverter 491 is lowered to VL level, thus the feedback output (FD1) 493 of AND gate 492 is lowered to VL level. After FD1 signal 493 is lowered to VL level, the NMOS transfer gate 463 and 464 are turned off, in order to cut off the current path, which reduces the active current after latching the data from the memory cell. Furthermore, the feedback output (FD2) 498 of the buffer 497 from AND gate 496 in the far end column 494 can be used to de-activate the word line 451 when it is connected to the control circuit (not shown). In the present invention, the detailed control circuits are not described in order to reduce unnecessary complexity, which is easily configured with the conventional circuit techniques.

In FIG. 5A, a block diagram is illustrated, as the present invention. When one of the main memory cells is selected in the block 540, the word line 541 is asserted. Simultaneously, the dummy word line 511 is asserted in the opposite block 510 and generates a reference voltage with the dummy circuit 520. In addition, the dummy word line is located in the middle of the array in order to generate more accurate reference voltage. The sense amp 530 receives the reference voltage from the dummy control circuit 520 and the stored data from the selected block 540. In FIG. 5B, more detailed dummy control circuits are illustrated, wherein a dummy read circuit 550 is connected to the dummy cell which stores data “1” (high resistance), and another dummy read circuit 560 is connected to the dummy cell which stores data “0” (low resistance). The dummy read circuit is the same as the main column as shown 450 in FIG. 4, but there is no feedback circuit because the dummy columns are turned on during read cycle. Hence, the switch 555, 556, 565 and 566 are turned on by the power line 554 and 564 when the dummy word line 551 is asserted.

In order to generate a reference voltage 564 and a sense amp enable signal 579. The dummy columns operate the same as main column 450 in FIG. 4 when read, as explained above. In doing so, the voltage output 564 is medium level between the data “1” and data “0” because the output 564 is connected two amplifiers, such that one amp generates high level, but another amp generates low level. The bit line is discharged to VL level before S1B signal is asserted to VL level, after then the dummy word line 551 is asserted. And then, S2B (to VL level) and S2T (to VH level) signals are asserted to enable the current detector circuit 570. Thus, NMOS 572A is turned off, and the current mirror 572 repeats the resistor line current and changes the latch node 573 from VH level to VL level because the resistor line starts to flow current after it is asserted to 2VTN level by the pull-up PMOS. And the sense amp enable 579 is lowered to VL level by changing the latch node 573 through inverters 574, 576, 577 and 578, where inverter 575 keeps the latch node 573, and inverter 577 and 578 can delay to enable the sense amp in order to have timing margin. In this manner, the sense amp (480 in FIG. 4) is enabled by the signal 579 (441 in FIG. 4).

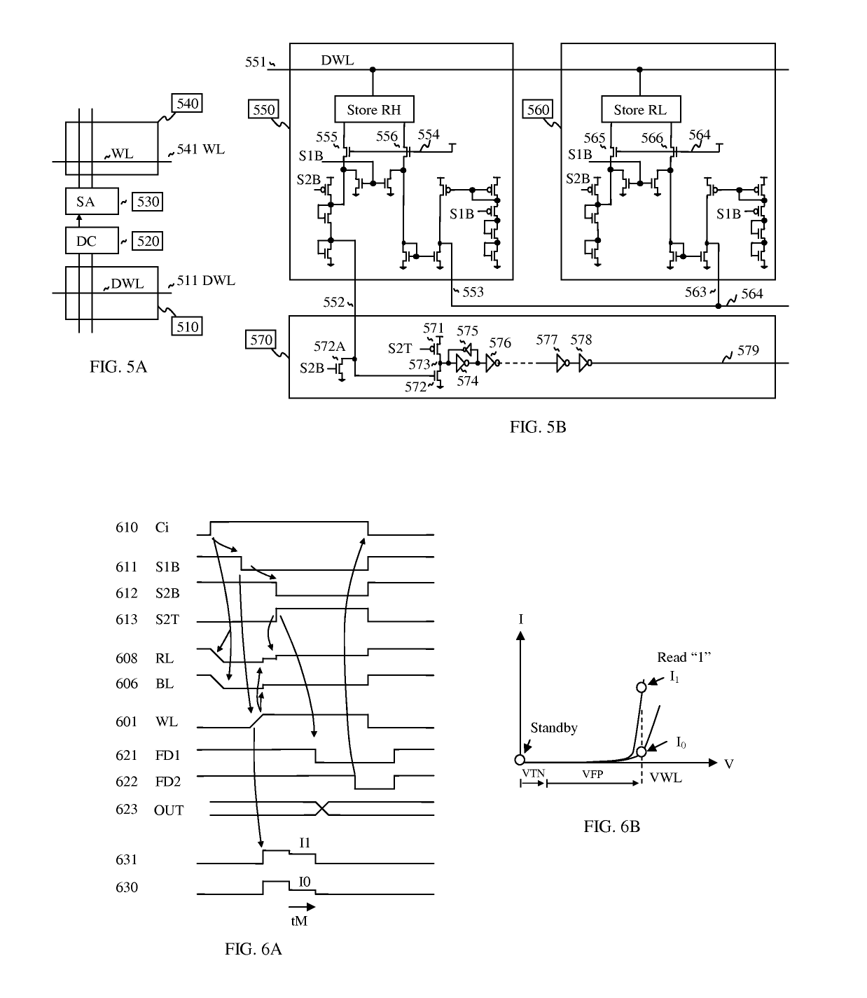

Referring now to FIG. 6A in view of FIG. 4, FIG. 5A and FIG. 5B, read timing is illustrated, as the present invention. In order to read, the column decoder signal (Ci) 610 is asserted to VH level firstly. By asserting Ci signal, the bit line (BL) 606 and the resistor line (RL) 608 are discharged from VH level to VL level, after then S1B signal is lowered to VL level, and then the word line (WL) 601 is asserted. By asserting the word line, the current path is set up, and the bit line 606 and the resistor line 608 are raised near the threshold voltage of the MOS transistor. After the current path is set up, S2B and S2T signal are asserted to measure the stored resistance of the storage element. By asserting S2B and S2T signal, the resistor line 608 is raised near 2VTN level. Thus the high current I1 is appeared in the bit line when the stored data is “1” as shown in 631, or the low current I0 is appeared when the stored data is “0” as shown 630. After then, the sense amp compares the measured voltage from the main memory cell and the reference voltage from the dummy cell, such that the pre-amp including the diode and the magnetoresistive storage element generates current output to the current-to-voltage amp, and the current-to-voltage amp including current mirror and generates voltage output, and finally the sense amp receives the voltage output from the current-to-voltage amp, which realize fast sensing. After sense amp generates voltage output 623, one of the latch nodes rises to VH level, which changes the feedback node FD1 621, which signal cuts off the current path of the bit line to reduce active current. Furthermore, the far end column output FD2 622 can be returned to the control circuit. Thus, all the control signals are pre-charged by the feedback signal FD2 622.

In FIG. 6B, the I-V curve of the memory cell is depicted. When reading data “1”, I1 current flows through the diode. On the contrary, when reading data “0”, the diode does not flow the current, which is I0 current (reverse bias leakage). And during standby, the word line is at ground level, which does not flow any current through the diode. When the word line is asserted, the word line voltage (VWL) is determined by the threshold voltage of the pull-down NMOS (VTN) and the built-in voltage of the p-n-p transistor (VFP), where the collector-emitter voltage of the p-n-p and n-p-n transistor may be ignored because the voltage drop of the collector-emitter voltage is very low with low turn-on resistance of the bipolar. After turning on, the feedback loop including p-n-p transistor and n-p-n transistor sustains the current path.

In the present invention, the memory operation is less sensitive to the temperature dependency of the threshold voltage of MOS transistor because the threshold voltage of MOS transistor is minus 1 mV/° C. (for bulk CMOS), minus 0.5 mV/° C. (for SOI CMOS), as published, “Temperature Dependency 0.1 um Partially Depleted SOI CMOSFET”, IEEE Electron Device Letters, Vol. 22, No. 7. pp. 339, July 2001. The threshold variation is much lower than the exhibiting voltage, such as 300 mV. Furthermore, built-in voltage of the diode does not affect the read operation because built-in voltage is applied to the word line, not the storage element, (minus 2 mV/° C. for silicon).

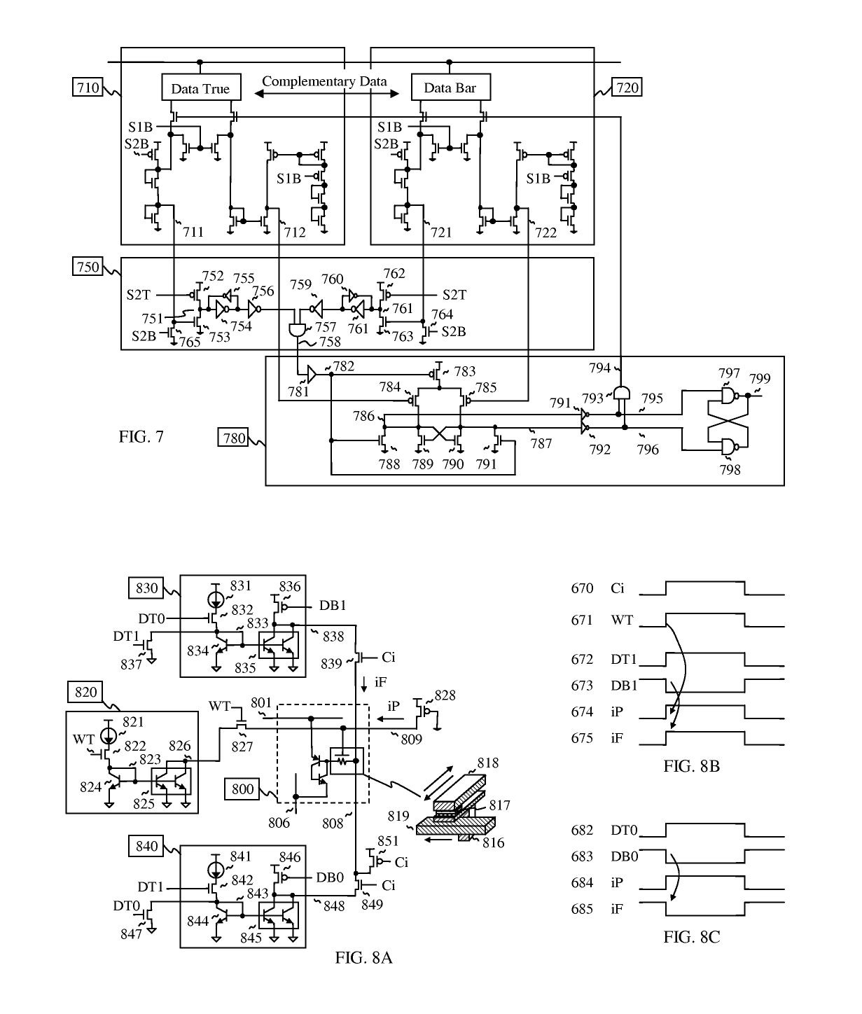

Referring now to FIG. 7, alternative array configuration including dual memory cells is illustrated, as the present invention, wherein two cells store a datum, the first memory cell serves as a (main) memory cell, and the second memory cell serves as a dummy cell, in order to have more sensing margin with the dummy cell and also achieve fast access. The (main) memory cell 710 stores non-inverting data, the dummy cell 720 stores inverting data, the current detector circuit 750 generates a sense amp enable signal 758, and the sense amplifier 780 compares the voltage difference of the two cells. The memory operation is similar to the array based on the single memory cell as explained above in FIG. 4. The difference is that the dummy cell stores inverting data, thus it generates an inverting voltage of the memory cell. As a result, the input voltage of the sense amp is about double, compared to the single memory cell array. And two memory cells limit the word line voltage when turned on. Thus, there are no other dummy cells to regulate the word line voltage. However, drawback is that the memory cell area is double. But this dual cell array is useful for fast memory, with more sensing margin, such as cache memory.

When read, the word line is asserted. And the bit line and resistor line are discharged as the single cell array in FIG. 4. Then, S1B signal is asserted to VL level. After then, S2B (to VL level) and S2T (to VH level) signal are asserted, thus NMOS 765 and 764 are turned off, and PMOS 752 and 762 are turned off, and the current mirror 753 and 763 repeat the current of the resistor lines. Hence, the latch node 751 and 761 are changed to VL level by the current mirror 753 and 763, after the S2T signal is turned off PMOS 752 and 762. After the latch nodes 751 and 761 are changed to VL level, the voltages are stored by the feedback inverter 755 and 760. And the latch node voltages are transferred to AND gate 757 through inverters 754 and 756, 761 and 759, respectively. And then, the AND gate 757 generates the sense amp enable signal 758, which signal is buffered by the buffer 781. Thus, the sense amp 780 is enables by the signal 782 (output of the buffer 781), such that the sense amp starts to compare the voltage difference between the non-inverting cell and the inverting cell. The pre-charge devices 788 and 791 are turned off, and simultaneously PMOS 783 is turned on. Hence PMOS 784 and 785, NMOS 789 and 790 are turned on, and amplify the voltage difference. As a result, one of the sense amp nodes 786 and 787 will rise near VH level, and another node will stay at VL level, which nodes changes inverters 791 and 792. Thus, one of the inverter outputs 795 and 796 drives the AND gate 793 to VL level, because one of two inverter output is at VL level. After the AND gate output 794 is reached to VL level, the currents path of the bit line are cut off, in order to reduce the active current after sensing the stored data from the memory cell. At the same time, the latch including NAND gate 797 and 798 keeps the read data. In addition, the latch including NAND gate 797 and 798 stores the data, even after the sense amp is in pre-charge state when S2T signal is lowered to VL level and other signals also are returned to pre-charge state, wherein the sense amp output 795 and 796 are at VH level during pre-charge state, thus the data from the memory cell is stored in the latch 797 and 798.

In FIG. 8A, the write circuit is illustrated, as the present invention, wherein the magnetic memory 800 is selected by flowing the write current through the write word line 809 and the resistor line 808, while the diode is turned off when the read word line 801 is lowered to VL level and the bit line 806 keeps VH level. The p-n-p-n diode does not flow current because the base-emitter directions are reverse biased. In order to write, the write word line 809 serves as a pinned magnetic layer, and flows current to a fixed orientation from the PMOS 828 to the current source (current mirror) 820 when NMOS switch 827 is turned on by WT signal. In doing so, the current source 820 sinks enough current through the current mirror 825. In the present invention, the current mirror uses bipolar transistor in order to sink more current with small area. Furthermore, the bipolar current mirror 825 uses multiple sink devices, which is more efficient to control the current with small reference current through the reference circuit 824, wherein the reference current source 821 flows low current through the sink device 824 when NMOS 822 is turned, thus the current mirror 825 sinks more current with the multiple number. As a result, the area is reduced and the sink current is higher. At the same time, the resistor line 808 serves as a free magnetic layer. The magnetic orientation of the free magnetic layer 808 can be switched between two stable states when sufficient magnetic field is applied. Conductors above and below the magnetic tunnel junction (MTJ) generate the fields necessary to switch the state of the free magnetic layer, where write pulse is sustained for the predetermined duration. More detailed write operation is illustrated, wherein the write word line 819 couples to the magnetic tunnel junction element 817, the resistor line 818 is attached to the magnetic tunnel junction element 817, in the right side of the figure.

In order to write data “1”, column decoder output Ci is selected to VH level. Thus, NMOS 839 and 849 are turned on, and PMOS 851 is turned off. After then, DB1 signal is asserted to VL level, which turns on PMOS pull-up 836 in the current source 830. At the same time, DT1 signal is asserted to VH level. Thus, NMOS 837 is turned on and the current sink circuit 835 is fully turned off by lowering the signal 833. And the current source 840 is enabled by asserting DT1 signal to VH level. The current iF is set up from PMOS 836 to the sink circuit 845, when DT1 signal turns on NMOS 842 and the reference current path from the reference current 841 to the sink circuit 844, and the current sink circuit 845 flows with multiplied numbers of the reference current. In contrast, when write data “0”, the reverse current path is set up from PMOS pull-up 846 to the current sink circuit 835, when DB0 signal is asserted to VL level, and DT0 signal is asserted to VH level. During write data “0”, the current sink circuit 845 is turned off by lowering the signal 843. In the write circuit, it is more efficient to flow more current by using bipolar current sink circuit, which also can reduce area.

In FIG. 8B, the timing diagram for write data “1” is illustrated, as the present invention. In order to write data “1”, the column decoder output (Ci) 670 is asserted to VH level and the write enable signal (WT) 671 is asserted to VH level. And DT1 signal 672 and DB1 673 signals are asserted. Thus, the forward current (iF) 675 is set up. At the same time, the write enable signal (WT) 671 sets up the current path (iP) 674 for the pinned magnetic layer. In order to write data “0”, the column decoder output (Ci) 670 is asserted to VH level and the write enable signal (WT) 671 is asserted to VH level the same as write data “1”. But DT0 signal 682 and DB0 683 signals are asserted. Thus, the reverse current (iF) 685 is set up. At the same time, the current path (iP) 684 for the pinned magnetic layer is set up.

### Methods of Fabrication

Replacing MOS access device with a diode access device, the memory cell needs only a p-n-p-n diode (or n-p-n-p diode) and a magnetoresistive storage element, which realizes new types of memory cell structure, in order to reduce cell area on the bulk or SOI (Silicon-on-Insulator) wafer. The steps in the process flow should be compatible with the current CMOS manufacturing environment. And the present invention uses similar techniques to fabricate the memory cell. There are many prior arts to form vertical magnetic memory, as published, U.S. Pat. No. 6,097,625, U.S. Pat. No. 6,272,041 and U.S. Pat. No. 6,944,049. Within the current CMOS manufacturing environment, there is no unknown or unpredictable process flow to form the memory cell for the present invention. In this respect, the present invention will avoid describing too much detailed process flow to form the memory cell, such as width, length, thickness, temperature, pressure, forming method or any other material related data. Instead of describing those details, the present invention focuses on illustrating the concept to form the new memory cell structures which are more practical and mass producible. In particular, the memory cells are formed in between the routing layers. Hence the memory cells can be stacked over the peripheral circuits, and alternatively multiple cells can be stacked on the wafer. In this manner, topping the memory cells is independent of the MOS process and the memory cells can be formed in the CMOS bulk or SOI wafer.

In order to form the diode on the metal routing layer, LTPS (Low Temperature Polysilicon) can be used to form the diode, as published, U.S. Pat. No. 5,395,804, U.S. Pat. No. 6,852,577 and U.S. Pat. No. 6,951,793. LTPS has been developed for the low temperature process (500 Celsius or lower) on the glass in order to apply the display panel, according to the prior arts. Now the LTPS can be used as a diode for the memory access device. Generally, polysilicon diode can flow less current than single crystal silicon diode, but the polysilicon diode can flow more current than MOS transistor, because the diode can flow the current through the whole junction while the MOS transistor can flow the current through the shallow inversion layer by the gate control. In the present invention, LTPS-based diode is useful to stack the diode-based memory cells with no very thin oxide layer, because the memory cell does not include MOS transistor. During polysilicon process, the MOS transistor in the control circuit and routing metal are less degraded.

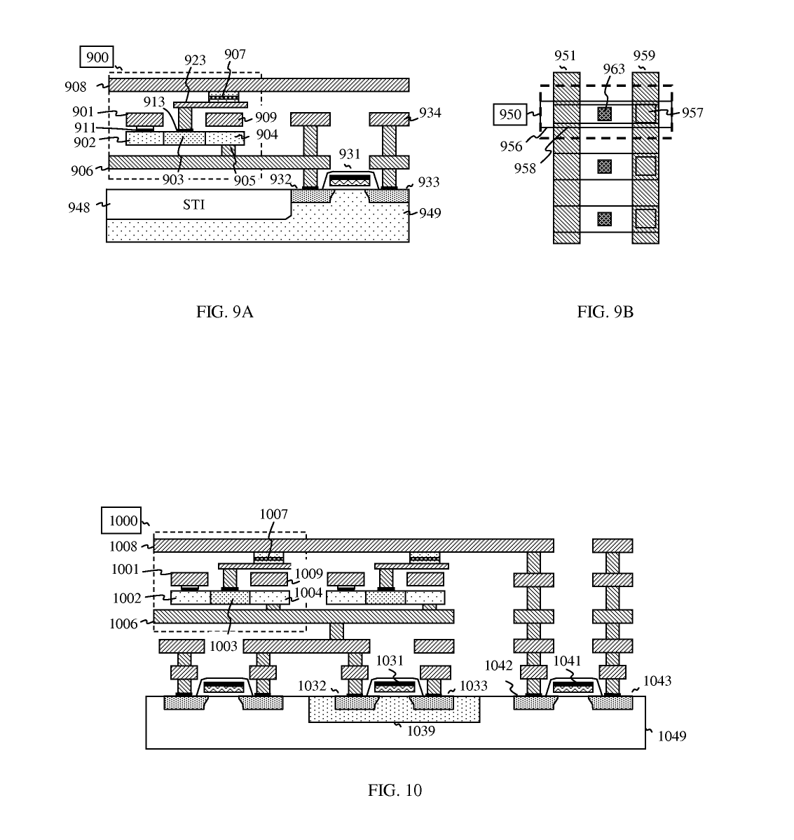

In FIG. 9A to 9B, one example of cell structure is illustrated, as the present invention. The memory cell 900 is formed on the wafer 949. And STI (Shallow Trench Isolation) layer 948 may be added in order to reduce parasitic capacitance of the bit line 906, alternatively. The MOS transistor is formed on the wafer, wherein the MOS transistor is configured such that the region 931 is a gate, the region 932 is a drain and the region 933 is a source. After forming the MOS transistor, the metal bit line 906 is formed, and then the metal contact region 905 is formed. After then, the diode layer is formed on the metal contact region 905. Thus, Schottky diode is formed between the contact region 905 and the p-type third terminal 904. And then the storage node 903 is formed by implanting n-type impurities. As a result, p-type first terminal 902 is separated by the n-type region 903. Then, ohmic contact region 911 with silicide is formed in order to connect the first terminal to the read word line 901. Then, the contact region 913 is plugged, and is connected to the region 923 in order to connect the magnetoresistive storage element (magnetic tunnel junction) 907. Then the resistor line 908 is formed on the magnetoresistive storage element 907. In doing so, the four-terminal diode and the magnetoresistive storage element are formed in between the routing layers. Thus, topping the memory cells on the MOS transistor is independent of the MOS transistor process, which realizes more flexibility to produce the semiconductor chip with magnetoresistive storage element. For example, topping the memory cells can be different fabrication facility because most of fabrication facility provides the MOS transistors only.

In FIG. 9B, top view of the memory cell 950 is illustrated, wherein the read word line 951 and the write word line 959 are in the same direction, but the bit line 956 and the resistor line 958 are perpendicular to the read word line 951 and the write word line 959, the magnetoresistive storage element 957 is on the write word line 959 in order to couple the storage element when write, and the contact region 963 is formed in order to connect the storage element to the storage node.

In FIG. 10, one example structure is illustrated, in order to form the memory cells on the MOS transistors as the present invention. The MOS transistors are formed on the surface of the wafer, wherein the region 1031 is a PMOS gate, the region 1032 is a drain and the region 1033 is a source on the n-type well region 1039. NMOS transistor is formed on the bulk, wherein the region 1041 is a NMOS gate, the region 1042 is a drain and the region 1043 is a source. After forming the MOS transistors, the memory cells are formed, such that the metal bit line 1006 is formed on the MOS transistor, the third terminal 1004 forms a Schottky diode with the metal contact region of the bit line, the third terminal 1004 is attached to the second terminal 1003, the second terminal 1003 is attached to the first terminal 1002, the storage element 1007 is connected to the second terminal, the read word line 1001 is connected to the first terminal 1002, the resistor line 1008 is formed on the storage element 1007.

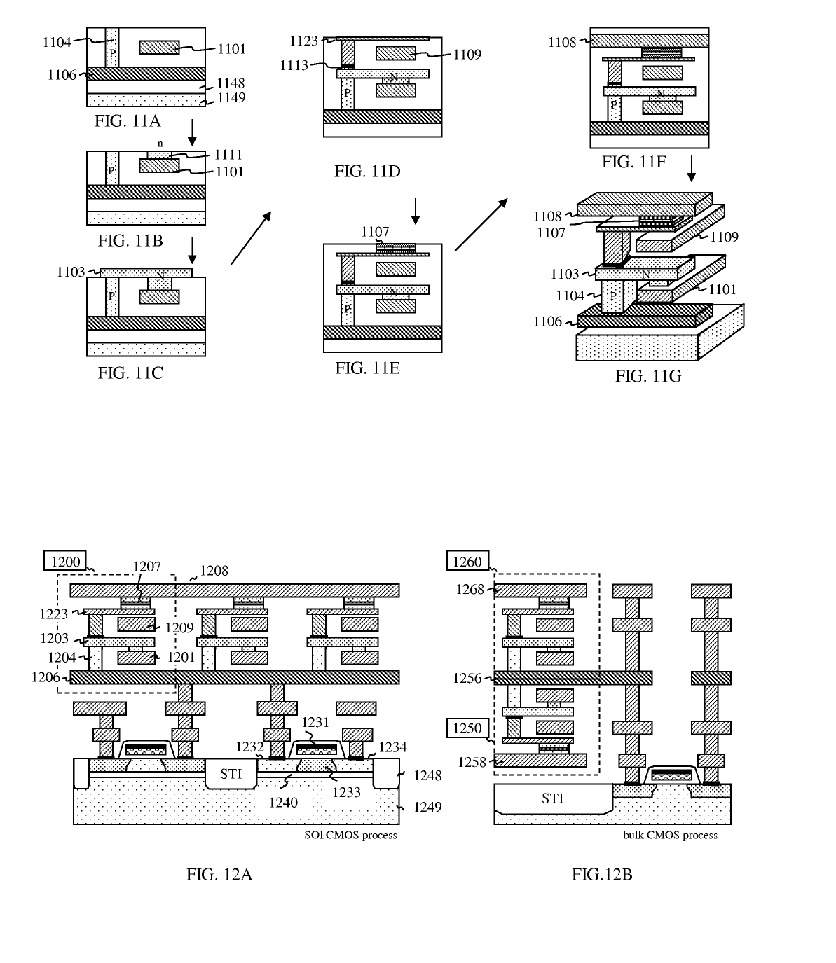

In FIG. 11A to 11G, brief process steps to form a magnetic memory are illustrated, as the present invention. As shown in FIG. 11A, the metal bit line 1106 is formed after adding the isolation layer 1148 on the wafer 1149, and then the metal read word line 1101 is formed. After forming the read word line 1101, the p-type third terminal 1104 is plugged and makes a Schottky diode with the metal bit line 1106. And then, in FIG. 11B, n-type region 1111 is formed on the metal word line 1101, thus another Schottky diode is formed to the read word line 1101 with n-type region 1111, as shown in FIG. 11C. Generally, Schottky diode has more reverse bias leakage, but the reverse bias leakage does not affect the memory operation in the present invention, because the memory cell operates in the forward bias region in active mode, and during standby the memory cells are turned off. In the magnetic memory, the stored data is in the magnetoresistive storage element. There are no charging elements in the memory cell. Alternatively, p-type semiconductor is formed after forming ohmic contact to the read word line 1101, in order to reduce reverse bias current. Thus, the p-type region 1111 becomes the first terminal, and forms a p-n junction to the second terminal 1103, where the p-type region 1111 is enough space to prevent the punch-through effect. (This alternative structure is not shown in the figure)

After forming the diode, contact region 1113 including silicide is formed, where contact region 1113 provides ohmic contact. And the contact region 1113 is connected to the conduction layer 1123, as shown in FIG. 11D. And then the storage element 1107 is formed on the layer 1123, as shown in FIG. 11E. After forming the magnetoresistive storage element, the metal resistor line 1108 is formed on the storage element, as shown in FIG. 11F. As a result, the memory cell is completed as shown in FIG. 11G.

In FIG. 12A, a vertical structure of the memory cell is illustrated, as the present invention, wherein the memory cells are formed on the MOS transistor, the MOS transistor is configured on the buried oxide 1240 of SOI wafer, such that the region 1231 is a gate, the region 1232 is a drain and the region 1233 is a source. After forming the MOS transistor, the memory cell 1200 is formed, wherein the memory cell structure is the same as above in FIG. 11G. The metal bit line 1206 is vertically attached to the third terminal 1204, the third terminal 1204 is attached to the second terminal 1203, a Schottky diode is formed with the metal read word line 1202 through a via region, the storage element 1207 is connected to the second terminal 1203 through ohmic contact region and conduction region 1233, the write word line 1209 is couples the storage element, and the resistor line 1208 is connected to the storage element 1207. In doing so, the vertical magnetic memory cells are formed on the MOS transistors, which can reduce cell area on the chip.

In FIG. 12B, a stacked structure of the memory cell is illustrated, as the present invention, wherein two memory cells are stacked. After forming the MOS transistor, the lower memory cell 1250 is formed, after then, the upper memory cell 1260 is formed, wherein the bit line 1256 is shared, the resistor line 1258 for the lower cell is in the bottom side, the resistor line 1268 for the upper cell is in the top side, and the memory cell structure is the same as above in FIG. 11G.

While the description here has been given for configuring the memory circuit and structure, alternative embodiments would work equally well with reverse connection such that the first terminal is n-type and serves as a word line, the second terminal is p-type and serves as a storage node, the third terminal is n-type and floating, and the fourth terminal is p-type and serves as a bit line. The signals are reversely moving to read and write data, such that active high signal becomes active low signal.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

What is claimed is:

1. A magnetic memory, comprising:
memory cell, wherein includes a storage element and a diode; and
the storage element, wherein includes a magnetic tunnel junction (MTJ) stack, the first electrode of the stack serves as a storage node, the second electrode of the stack serves as a free magnetic layer which serves as a resistor line, and the stack is coupled to a pinned magnetic layer which serves as a write word line; and the diode as an access device, wherein includes four terminals, the first terminal is connected to a read word line, the second terminal is connected to the storage node, and the third terminal is floating, and the fourth terminal is connected to a bit line; and the bit line and the resistor line are in parallel while the read word line and the write word line are perpendicular to the bit line and the resistor line in direction; and
read circuits, wherein include a pre-amp, a current-to-voltage amp and a sense amp, the pre-amp is connected to the storage element and the diode through the bit line, the current-to-voltage amp is connected to the pre-amp, and the sense amp is connected to the current-to-voltage amp, and the output of sense amp cuts off the current path of the pre-amp through the bit line after latching data.

2. The magnetic memory of claim 1, wherein the diode includes four-terminals, the first terminal is p-type, the second terminal is n-type, the third terminal is p-type, and the fourth terminal is n-type.

3. The magnetic memory of claim 1, wherein the diode includes four-terminals, the first terminal is n-type, the second terminal is p-type, the third terminal is n-type, and the fourth terminal is p-type.

4. The magnetic memory of claim 1, wherein the diode is formed from silicon including polysilicon, amorphous silicon, and stretchable silicon.

5. The magnetic memory of claim 1, wherein the diode is formed from germanium, or compound semiconductor.

6. The magnetic memory of claim 1, wherein at least one terminal of the diode includes metal to form Schottky diode.

7. The magnetic memory of claim 1, wherein the storage element includes CoFe and Al₂O₃.

8. The magnetic memory of claim 1, wherein the storage element includes IrMn for the free magnetic layer and CoFe—Ru—CoFe—Al₂O₃—NiFe for the pinned magnetic layer.

9. The magnetic memory of claim 1, wherein the pre-amp includes a diode as receiving device and an active load wherein the gate and the drain are connected together.

10. The magnetic memory of claim 1, wherein the current-to-voltage amp includes the current mirror as a receiving device and an active load.

11. The magnetic memory of claim 1, wherein the pre-amp, the current-to-voltage amp and the sense amp include lower threshold voltage than that of control circuits.

12. The magnetic memory of claim 1, wherein the sense amp receives a reference voltage from two dummy cells, where one dummy cell store inverting data and another dummy cell stores non-inverting data.

13. The magnetic memory of claim 1, wherein the sense amp receives a reference voltage from a dummy cell, where the dummy cells stores inverting data while the (main) memory cell stores non-inverting data, which configure dual memory cell array to store a datum.

14. The magnetic memory of claim 1, wherein the sense amp receives a reference voltage from a dummy cell, where the dummy cell stores non-inverting data while the (main) memory cell stores inverting data, which configure dual memory cell array to store a datum.

15. The magnetic memory of claim 1, wherein the write word line and the resistor line are driven by the bipolar current mirror which flows multiplied current from the reference current, when write.

16. The magnetic memory of claim 1, wherein the memory cells are formed in between the routing layers.

17. The magnetic memory of claim 1, wherein the memory cells are formed on the MOS transistors.

18. The magnetic memory of claim 1, wherein two memory cells are stacked on the wafer.

19. The magnetic memory of claim 1, wherein the memory cells are formed on the bulk of the wafer.

20. The magnetic memory of claim 1, wherein the memory cells are formed on the SOI wafer.
